(19) United States
(12) Patent Application Publication
(10) Pub. No.: US 2011/0266144 A1
(43) Pub. Date: Nov. 3, 2011

(54) SPUTTERING APPARATUS

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/910,844

(22) Filed: Oct. 24, 2010

(30) Foreign Application Priority Data
Apr. 28, 2010 (TW) 99113582

(51) Int. Cl. C23C 14/50; C23C 14/34

(52) U.S. Cl. 204/298.09

(57) ABSTRACT

A sputtering apparatus for coating workpieces includes a preheating case defining a preheating cavity, a deposition case defining a deposition cavity, a bridge assembly connecting the preheating case to the deposition case, two supporting assemblies, posts for fixing the workpieces, and a transmission assembly positioned in the preheating case. The bridge assembly includes a bridge member defining a passage and a valve moveably connected to the bridge member. The valve communicates the preheating cavity with the deposition cavity through the passage or separates the preheating cavity from the deposition cavity. One supporting assembly is received in the preheating cavity, and the other supporting assembly is received in the deposition cavity. The transmission assembly removes the posts from one of the supporting assemblies and fixes the posts to the other supporting assembly.

### BACKGROUND

1. Technical Field

The present disclosure relates to coating technologies and, particularly, to a sputtering apparatus.

2. Description of Related Art

Generally, during coating process employing sputtering, a plurality of workpieces such as device housings are placed in an airtight chamber from which air is removed by a vacuum pump, after which an inert gas is introduced in the chamber to excite energized ions. The energized ions bombard a solid target material, vaporizing the same. The vaporized material is then deposited on the workpieces. After a set of workpieces is completely coated, the chamber is opened and the vacuum state is broken. The set of workpieces can be moved out of the chamber. Subsequent workpieces are then placed in the chamber for the next sputtering process. However, during the vacuum state break, the target material is easily oxidized by air or contaminated by dust, in which case coating efficiency and quality are influenced.

Therefore, what is needed is to provide a sputtering apparatus which can overcome the described limitations.

### BRIEF DESCRIPTION OF THE DRAWINGS

FIG. 1 is a schematic, isometric view of a sputtering apparatus including two rotating assemblies and a transmission assembly, according to an exemplary embodiment, showing the transmission assembly in a first state.

FIG. 2 is an enlarged view of a circled part II of the rotating assembly of FIG. 1.

FIG. 3 is an enlarged view of a circled part III of the rotating assembly of FIG. 1.

FIG. 4 is similar to FIG. 1, but shows the transmission assembly in a second state.

### DETAILED DESCRIPTION

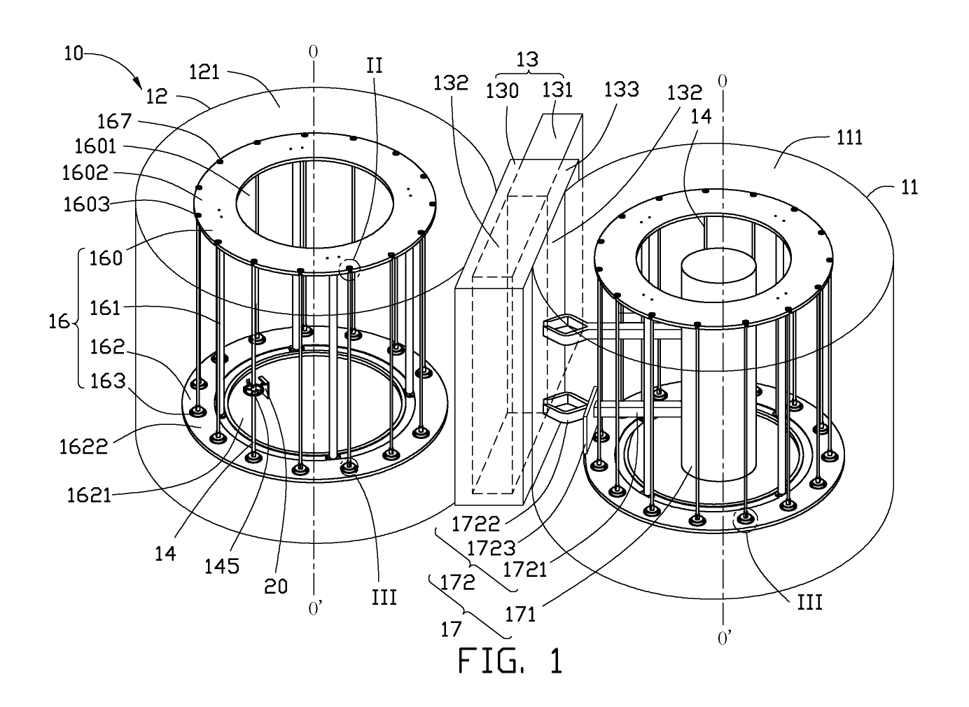

Referring to FIG. 1, a sputtering apparatus 10 for forming coatings on a plurality of workpieces (not shown), according to an exemplary embodiment, includes a preheating case 11, a deposition case 12, a bridge assembly 13, two supporting assemblies 16, a plurality of posts 14, and a transmission assembly 17.

The structure of the preheating case 11 is the same as that of the deposition case 12 in this embodiment. The preheating case 11 defines a preheating cavity 111. The deposition case 12 defines a deposition cavity 121.

The bridge assembly 13 includes a bridge member 130 and a valve 131. The bridge member 130 connects the preheating case 11 to the deposition case 12. The bridge member 130 defines a passage 132. The passage 132 communicates with the preheating cavity 111 and the deposition cavity 121. In this embodiment, the bridge member 132 is substantially cuboid and includes four sidewalls. An opening 133 is defined in a sidewall of the bridge member 132. The valve 131 conforms to the opening 133 and the passage 132. The valve 131 extends through the opening 133 and is received in the passage 132 in an airtight manner The passage 132 is sealed and divided into two sub-passages (not shown) by the valve 131. That is, the preheating cavity 111 is separated from the deposition cavity 121 by the valve 131.

The two supporting assemblies 16 have the same structure. One supporting assembly 16 is received in the preheating cavity 111, and the other in the deposition cavity 121. Each supporting assembly 16 defines a first axis 00′ in the center of the supporting assembly 16. The supporting assembly 16 can rotate about the first axis 00′.

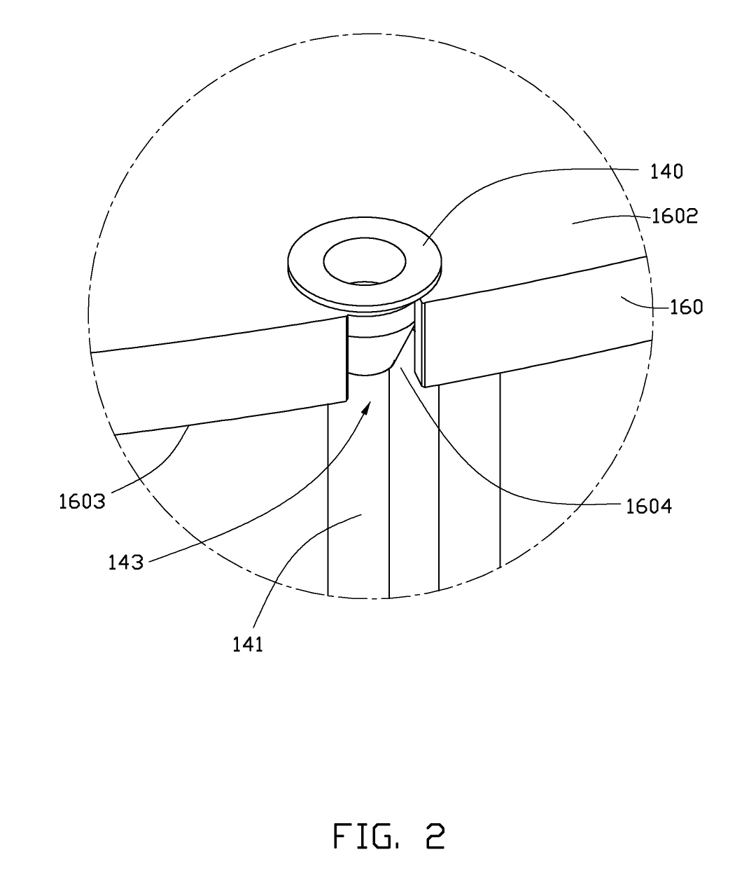

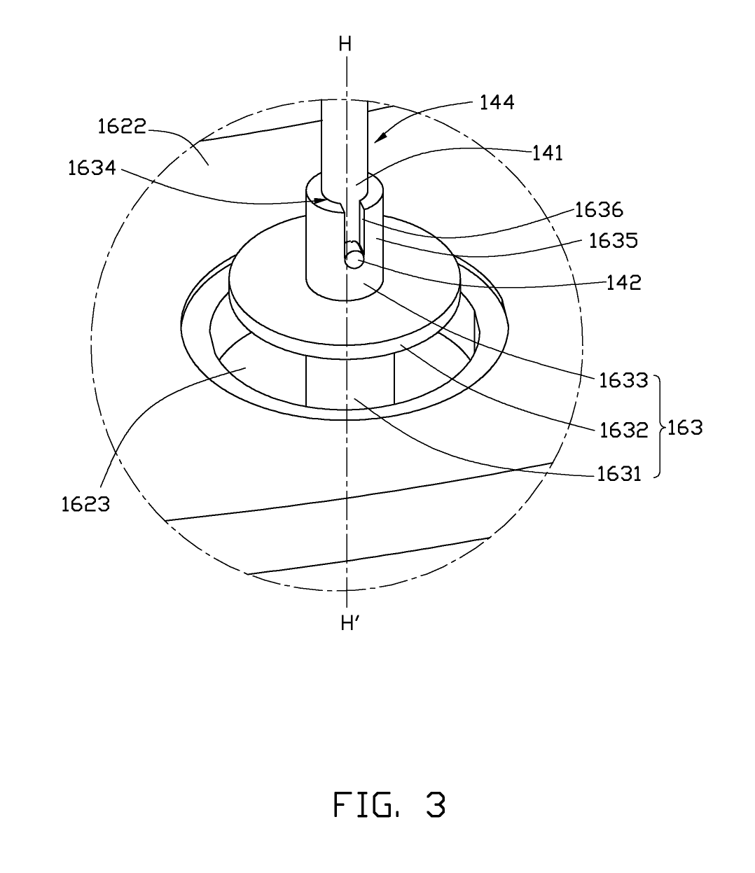

Also referring to FIGS. 2-3, the supporting assembly 16 includes an upper base 160, a lower base 162, a seat member 163, and four connecting posts 161.

The upper base 160 is an annular planar plate and defines an upper through hole 1601 at a center thereof. The upper base 160 includes a first surface 1602 and a second surface 1603. The first surface 1602 and the second surface 1603 are at opposite sides of the upper base 160. A plurality of cutouts 1604 through the first surface 1602 and the second surface 1603 is defined on an edge of the upper base 160. The cutouts 1604 substantially taper away from the upper through hole 1601. The diameter of each cutout 1604 decreases from the first surface 1602 to the second surface 1603. In this embodiment, the cutouts 1604 are equidistant around the first axis OO′.

The lower base 162 is an annular planar plate and defines a lower through hole 1621 aligned with the upper through hole 1601. The lower base 162 includes a third surface 1622 facing the second surface 1603. A plurality of first receiving holes 1623 is defined in the third surface 1622 aligned with the cutouts 1604 and corresponding to the seat members 163.

Each seat member 163 is rotatably received in a corresponding first receiving hole 1623. Each seat member 163 includes a supporting post 1631, a supporting base 1632, and a cylindrical engaging post 1633. The supporting post 1631 is received in a corresponding first receiving hole 1623 and can rotate about a second axis HH′ substantially parallel to a longitudinal axis thereof. The supporting base 1632 is fixed to an upper end of the supporting post 1631 and rotates about the second axis HH′ with the rotation of the supporting post 1631. The engaging post 1633 extends from the supporting base 1632 away from the third surface 1622. The engaging post 1633 defines a second receiving hole 1634. A slot 1636 is defined in a sidewall 1635 of the engaging post 1633. In this embodiment, the engaging post 1633 is coaxial with the supporting post 1631. Therefore, the engaging post 1633 can rotate about the second axis HH′ with the rotation of the supporting post 1631. In other words, the seat member 163 rotates about the second axis HH′.

The four connecting posts 161 are positioned between the second surface 1603 and the third surface 1622. The four connecting posts 161 connect the upper base 160 to the lower base 162. The four connecting posts 161 are spaced from the cutouts 1604 and the first receiving holes 1623. In this embodiment, the four connecting posts 161 are equidistant around the first axis OO′.

The posts 14 are supported by the supporting assembly 16 and are configured for fixing the workpieces. Each post 14 includes a body portion 141, an engaging portion 140, a protrusion 142, and a plurality of supporting arms 145. The body portion 141 is a cylinder and includes a first end 143 and a second end 144 conforming to the second receiving hole 1634. The first end 143 and the second end 144 are at opposite sides of the body portion 141. The engaging portion 140 extends from the first end 143 along the longitudinal axis of the body portion 141. The diameter of the body portion 141 is less than that of the least diameter of the cutout 1604. The engaging portion 140 has a tapered section conforming to the cutout 1604. The protrusion 142 extends radially from the second end 144 conforming to the slot 1636. The supporting arms 145 are configured for supporting the workpieces 20.

When a post 14 is assembled to the supporting assembly 16, the post 14 is lifted to raise the engaging portion 140 above the first surface 1602, elevate the second end 144 above the engaging post 1633, and align the protrusion 142 with the slot 1636. The post 14 is then moved toward the third surface 1622 until the cutout 1604 receives the engaging portion 140 and the second end 144 is received in the second receiving hole 1634 and the slot 1636 receives the protrusion 142. Thus, the engaging portion 140 is positioned by the cutout 1604 and the second end 144 is positioned in the seat member 163 via the protrusion 142 being blocked by the slot 1636. As a result, the post 14 can rotate about the second axis HH′ with the rotation of the seat member 163. When the post 14 is disassembled from the supporting assembly 16, the post 14 is lifted to raise the engaging portion 140 above the first surface 1602 and to elevate the second end 144 above engaging post 1633. The post 14 is then radially moved away from the first axis OO′ to separate from the supporting assembly 16.

The transmission assembly 17 includes a receiving case 171, a driver (not shown), and two retractable manipulators 172. The receiving case 171 is positioned in the preheating case 11 and passes through the upper through hole 1601 and the lower through hole 1621. The driver is received in the receiving case 171. Each manipulator 172 includes an arm 1721, a grip 1722 extending from the arm 1721, and a spatula 1723 between the arm 1721 and the grip 1722. The arms 1721 are received in the receiving case 171, and the grips 1722 exposed at the receiving case 171. The driver is mechanically and electrically connected to the manipulators 172. When the driver is implemented, the arms 1721 protrude out of or retract into the receiving case 171. The arms 1721 can also move downward or upward and the grips 1722 clamp a post 14.

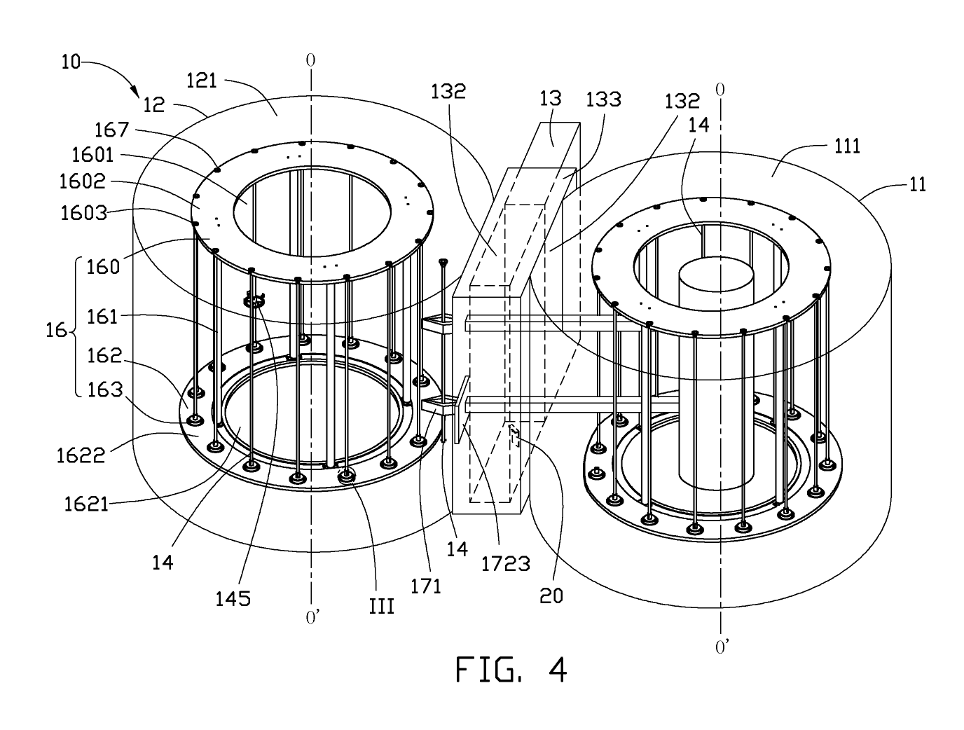

Also referring to FIG. 4, the transmission assembly 17 is implemented to transfer the posts 14 to the deposition case 12 and fix the posts 50 to the supporting assembly 16 therein. In particular, the grips 1722 are driven to clamp a post 14 in the preheating case 11. The arms 1721 are moved upward along the first axis OO′ until the engaging portion 140 is above the first surface 1602 and the second end 144 is above the engaging post 1633. The arms 1721 are then driven out of the preheating case 11 and enter the deposition case 12 to correspond to the supporting assembly 16 therein. The arms 1721 are finally moved downward along the first axis OO′ until the cutout 1604 receives the engaging portion 140 and the second end 144 is received in the second receiving hole 1634 and the slot 1636 receives the protrusion 142. The grips 1722 release the post 14 and the arms 1721 retract into the receiving case 171 for transferring the next post 14. If the workpiece 20 is unexpectedly dropped in the passage 132 of the bridge assembly 13 in the transportation process, the valve 131 will be not received in the passage 132. In the transport process, the workpiece 20 is pushed away from the passage 132 by the spatula 1723 of the manipulator 172. In this embodiment, the arms 1721 move in a direction perpendicular to the first axis OO′.

It is to be understood, however, that even though numerous characteristics and advantages of the present embodiments have been set forth in the foregoing description, together with details of the structures and functions of the embodiments, the disclosure is illustrative only, and changes may be made in details, especially in matters of shape, size, and arrangement of parts within the principles of the invention to the full extent indicated by the broad general meaning of the terms in which the appended claims are expressed.

What is claimed is:

1. A sputtering apparatus for forming coatings on a plurality of workpieces, comprising:
a preheating case defining a preheating cavity;
a deposition case defining a deposition cavity;
a bridge assembly connecting the preheating case to the deposition case, the bridge assembly comprising a bridge member defining a passage and a valve, the valve moveably connected to the bridge member, the valve configured for directing the preheating cavity to communicate with the deposition cavity through the passage or directing the preheating cavity to separate from the deposition cavity;
two supporting assemblies, one received in the preheating cavity, the other received in the deposition cavity;
a plurality of posts configured for fixing the workpieces, and
a transmission assembly positioned in the preheating case, the transmission assembly comprising a receiving case and a plurality of retractable manipulators, the manipulators configured for disassembling the posts from one of the supporting assemblies and assembling the posts to the other supporting assembly.

2. The sputtering apparatus as claimed in claim 1, wherein the bridge member is substantially cuboid and comprises four sidewalls, an opening is defined in a sidewall of the bridge member, and the valve conforms to the opening and the passage, and the valve extends through the opening and is tightly received in the passage so that the passage is sealed and is divided into two sub-passages by the valve.

3. The sputtering apparatus as claimed in claim 2, wherein each supporting assembly defines a first axis in the center thereof, about which the supporting assembly rotates.

4. The sputtering apparatus as claimed in claim 3, wherein each supporting assembly comprises an upper base, a lower base, a seat member, and at least two connecting posts, and the upper base is opposite to the lower base, the seat member is mounted to the lower base facing the upper base, and the connecting posts are positioned between the upper base and the lower base and connect the upper base to the lower base.

5. The sputtering apparatus as claimed in claim 4, wherein the upper base comprises a first surface and a second surface opposite to the first surface, a plurality of cutouts through the first surface and the second surface are defined on an edge of the upper base away from the first axis, the lower base comprises a third surface opposite to the second surface, a plurality of first receiving holes are defined in the third surface aligned with the cutouts and corresponding to the seat members, the seat members are rotatably received in the corresponding first receiving holes, and the cutouts and the seat members cooperatively assemble the posts to the supporting assembly.

6. The sputtering apparatus as claimed in claim 5, wherein the cutouts are substantially tapered, the diameter of each cutout decreasing from the first surface to the second surface, each seat member comprises a supporting post, a supporting base, and a cylindrical engaging post, the supporting post is received in a corresponding first receiving hole and rotates about a second axis substantially parallel to a longitudinal axis thereof, the supporting base is fixed to an upper end of the supporting post, the engaging post extends from the supporting base away from the third surface, and each post is received in the cutout and the engaging post and rotates about the second axis with the rotation of the seat member.

7. The sputtering apparatus as claimed in claim 6, wherein the engaging post defines a second receiving hole, a slot is defined in a sidewall of the engaging post, the engaging post is coaxial with the supporting post, each post comprises a body portion, an engaging portion, and a protrusion, the body portion comprises a first end and a second end opposite to the first end conforming to the second receiving hole, the engaging portion extends from the first end along the longitudinal axis of the body portion, the diameter of the body portion is less than that of the least diameter of the cutout, the engaging portion has a tapered section conforming to the cutout, the protrusion radially extends from the second end conforming to the slot, the engaging portion is received in the cutout, the second end is received in the second receiving hole, and the protrusion is received in the slot.

8. The sputtering apparatus as claimed in claim 7, wherein the upper base is an annular planar plate and defines an upper through hole at a center thereof, the lower base is an annular planar plate and defines a lower through hole aligned with the upper through hole, and the transmission assembly passes through the upper through hole and the lower through hole of the supporting assemblies in the preheating cavity.

9. The sputtering apparatus as claimed in claim 8, wherein each manipulator comprises an arm, a grip and a spatula position between the arm and the grip, the arm is received in the receiving case, the grip is exposed at the receiving case, the arm is configured for protruding out of or retracting into the receiving case, moving downward or upward, the grip is configured for clamping the posts, and the spatula is configured for pushing away the workpieces in the passage of the bridge assembly.
